(19) United States
(12) Patent Application Publication
(10) Pub. No.: US 2021/0384752 A1
(43) Pub. Date: Dec. 9, 2021

(54) ELECTRONIC DEVICE AND CONTROL METHOD

(71) Applicant: CANON KABUSHIKI KAISHA, Tokyo (JP)

(72) Inventor: Hiromi Hayasaki, Kanagawa (JP)

(21) Appl. No.: 17/338,136

(22) Filed: Jun. 3, 2021

(30) Foreign Application Priority Data
Jun. 9, 2020 (JP) 2020-100041

(51) Int. Cl. H02J 7/00; H04R 1/10; H04R 3/00; G01R 19/165

(52) U.S. Cl. CPC H02J 7/007188; H02J 7/0047; H04R 1/1025; H04R 2420/09; H04R 1/1041; H04R 3/00; G01R 19/16538; H04R 1/1008

(57) ABSTRACT

An electronic device includes a charging unit and a control unit. The control unit inhibits the charging unit from charging a battery in a case where audio recording using a first microphone is performed, and permits the charging unit to charge the battery in a case where audio recording using a second microphone different from the first microphone is performed.

### BACKGROUND

### Field of the Disclosure

Aspects of the disclosure generally relate to an electronic device and a method of controlling the electronic device.

### Description of the Related Art

Japanese Patent Application Laid-Open No. 9-233414 discusses a method for enabling clear audio recording while reducing the occurrence of noise from electric parts by inhibiting activation of the electric parts when an audio input unit is operating.

However, according to the method discussed in Japanese Patent Application Laid-Open No. 9-233414, the activation of the electric parts is inhibited when the audio input unit is operating, so the battery cannot be charged at the time of audio recording.

### SUMMARY

According to various embodiments of the disclosure, an electric device is provided which is capable of charging of a battery in performing audio recording.

According to various embodiments of the disclosure, there is provided an electronic device that includes a charging unit that charges a battery, and a control unit that inhibits the charging unit from charging the battery in a case where audio recording using a first microphone is performed, and permits the charging unit to charge the battery in a case where audio recording using a second microphone different from the first microphone is performed.

According to various embodiments of the disclosure, there is provided a method that includes causing a charging unit to charge a battery, inhibiting the charging unit from charging the battery in a case where audio recording using a first microphone is performed, and permitting the charging unit to charge the battery in a case where audio recording using a second microphone different from the first microphone is performed.

Further aspects of various embodiments of the disclosure will become apparent from the following description of exemplary embodiments.

### BRIEF DESCRIPTION OF THE DRAWINGS

FIG. 1 is a diagram illustrating components of an electronic device according to first and second exemplary embodiments.

FIG. 2 is a flowchart illustrating an example of operation of the electronic device according to the first and second exemplary embodiments.

FIG. 3 is a flowchart illustrating an example of a moving image capture process according to the first exemplary embodiment.

FIG. 4 is a flowchart illustrating an example of a voice memo recording process according to the first and second exemplary embodiments.

FIG. 5 is a flowchart illustrating an example of a battery charging process according to the first and second exemplary embodiments.

FIG. 6 is a flowchart illustrating an example of a moving image capture process according to the second exemplary embodiment.

### DESCRIPTION OF THE EMBODIMENTS

Exemplary embodiments, features, and aspects of the disclosure will be described below with reference to the drawings. However, it is noted that embodiments, features, and aspects of the disclosure are not limited to the following embodiments.

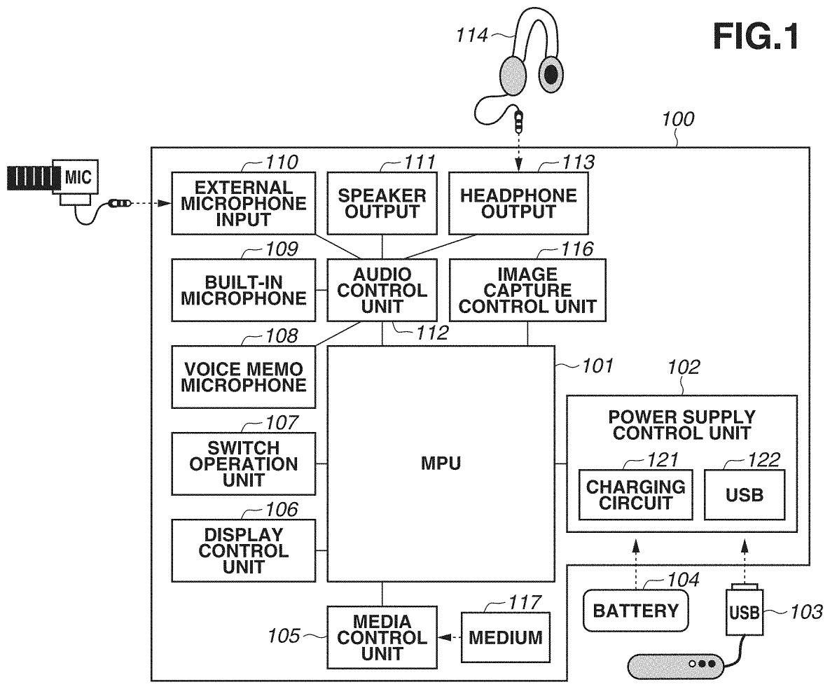

FIG. 1 is a diagram illustrating components of an electronic device 100 in first and second exemplary embodiments. The electronic device 100 in the first and second exemplary embodiments is an electronic device that has an audio recording function for recording audio and an imaging function for capturing still images and moving images. The electronic device 100 has a microcomputer (MPU) 101, a power supply control unit 102, a media control unit 105, a display control unit 106, and a switch operation unit 107. The electronic device 100 also has a voice memo microphone 108, a built-in microphone 109, an external microphone input 110, a speaker output 111, an audio control unit 112, a headphone output 113, and an image capture control unit 116.

When a battery 104 is connected to the electronic device 100, the power supply control unit 102 starts to supply electric power to the MPU 101 that controls the entire electronic device 100. The power supply control unit 102 has a charging circuit 121 for the battery 104 and a Universal Serial Bus (USB) control circuit 122. The power supply control unit 102 also has a voltage check circuit, and a direct-current/direct-current (DC/DC) converter.

When a power switch of the switch operation unit 107 is turned from the off state to the on state, the MPU 101 commands the power supply control unit 102 to check the voltage of the connected battery 104. If the voltage of the battery 104 is higher than a predetermined voltage, the MPU 101 causes the display control unit 106 to provide a startup display on a display device (such as a liquid crystal display (LCD)), and executes processes for starting the electronic device 100. If the voltage of the battery 104 is equal to or lower than the predetermined voltage, the MPU 101 causes the display control unit 106 to provide a display for prompting a user to replace the battery.

When the electronic device 100 is started normally, the switch operation unit 107 makes settings of an imaging mode and imaging parameters to prepare for image capturing. When a release start switch of the switch operation unit 107 is pressed, still image capturing is started. When a recording start switch of the switch operation unit 107 is pressed, moving image capturing is started. The still image or the moving image captured by the electronic device 100 is processed by the image capture control unit 116.

In moving image capturing, the electronic device 100 also records audio by using the built-in microphone 109 or an external microphone 115. The electronic device 100 incorporates the voice memo microphone 108 with which imaging conditions and an imaging location can be added as a voice memo to the captured still image. Microphones in the electronic device 100 are switchable as appropriate according to the intended use. When the external microphone 115 is connected to the external microphone input 110, the electronic device 100 changes the audio input during moving image capturing from the built-in microphone 109 to the external microphone 115. Audio signals from the built-in microphone 109, the external microphone 115, and the voice memo microphone 108 are processed by the audio control unit 112. When headphones 114 are connected to the headphone output 113, audio from the built-in microphone 109, the external microphone 115, or the voice memo microphone 108 is output to the headphones 114.

The still image data and the moving image data including audio data are stored by the media control unit 105 in a recording medium 117 under control of the MPU 101. The press of a playback button of the switch operation unit 107 reproduces the captured still image or moving image. The reproduced still image or moving image is displayed on the display device (such as an LCD) by the display control unit 106, and the reproduced audio is output through the speaker output 111. When the headphones 114 are connected to the headphone output 113, the reproduced audio is output to the headphones 114, not to the speaker output 111.

When a device 103 compliant with the USB Power Delivery (PD) standard is connected to a USB terminal of the power supply control unit 102, the electronic device 100 can drive the charging circuit 121 of the power supply control unit 102 to charge the battery 104. When charging of the battery 104 is started, the electronic device 100 causes the display control unit 106 to provide an LED display indicating that the battery 104 is under charging. The electronic device 100 may cause the display control unit 106 to display the amount of charge of the battery 104 by percentage on the display device (e.g., an LCD).

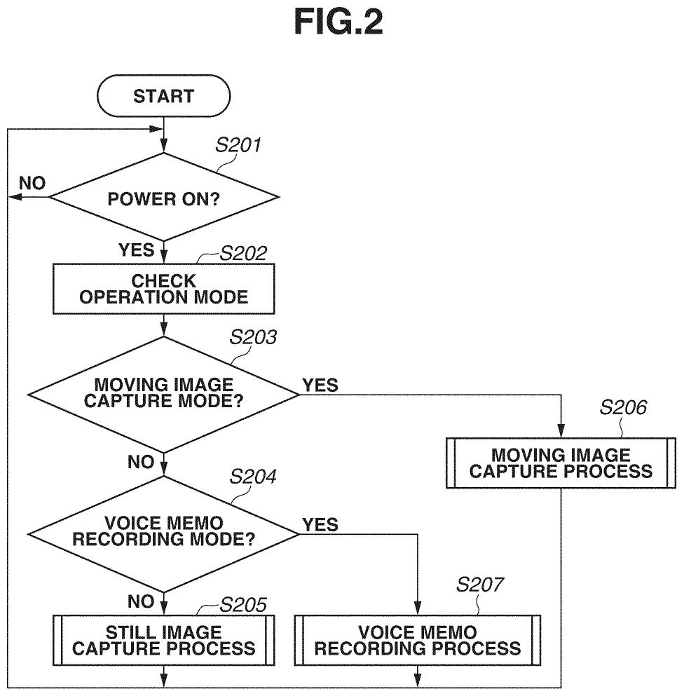

Hereinafter, operations related to charging control with the use of a microphone performed by the electronic device 100 in the first exemplary embodiment will be described with reference to FIGS. 2 to 5. Each process in the flowchart described below is controlled by the MPU 101 of the electronic device 100 executing a program stored in the memory. FIG. 2 is a flowchart illustrating an example of the operation of the electronic device 100 according to the first and second exemplary embodiments.

In step S201, the MPU 101 starts the electronic device 100 when the power switch is turned from the off state to the on state. The MPU 101 is in the standby state until the power switch is turned from the off state to the on state. When the power switch is turned to the on state (YES in step S201), the MPU 101 proceeds to step S202.

In step S202, the MPU 101 checks the currently set operation mode. The operation mode is set based on a setting operation performed using the switch operation unit 107. In the first exemplary embodiment, a description will be given of operation modes for performing still image capturing, moving image capturing, or audio recording, and operation modes for performing still image reproduction, moving image reproduction, or audio reproduction will not be described.

In step S203, the MPU 101 determines whether the operation mode is a moving image capture mode. In a case where the MPU 101 determines that the operation mode is the moving image capture mode (YES in step S203), the MPU 101 proceeds to step S206. In a case where the MPU 101 determines that the operation mode is not the moving image capture mode (NO in step S203), the MPU 101 proceeds to step S204.

In step S204, the MPU 101 determines whether the operation mode is a voice memo recording mode. In a case where the MPU 101 determines that the operation mode is the voice memo recording mode (YES in step S204), the MPU 101 proceeds to step S207. In a case where the MPU 101 determines that the operation mode is not the voice memo recording mode (NO in step S204), the MPU 101 proceeds to step S205.

In step S205, the MPU 101 performs a still image capture process. In the still image capture process, when the release start switch of the switch operation unit 107 is pressed, the still image capturing is started. Since audio recording is not performed in the still image capture process, detailed description of audio recording will be omitted here. When the still image capture process is ended, the MPU 101 returns to step S201. In step S201, the MPU 101 repeats the operation described above.

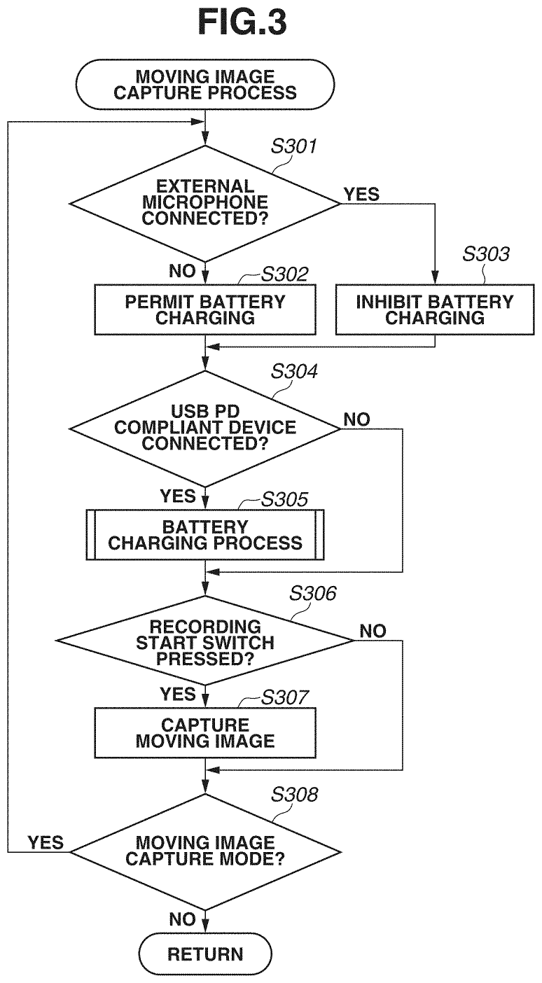

In step S206, the MPU 101 performs a moving image capture process. When the moving image capture process is ended, the MPU 101 returns to step S201. In step S201, the MPU 101 repeats the operation described above. Here, an example of the moving image capture process performed in step S206 of FIG. 2 will be described with reference to the flowchart of FIG. 3. FIG. 3 is the flowchart illustrating the example of the moving image capture process according to the first exemplary embodiment.

In step S301, the MPU 101 determines whether the external microphone 115 is connected to the external microphone input 110. In a case where the MPU 101 determines that the external microphone 115 is not connected (NO in step S301), the MPU 101 proceeds to step S302. In a case where the MPU 101 determines that the external microphone 115 is connected (YES in step S301), the MPU 101 proceeds to step S303.

In step S302, the MPU 101 sets a battery charging permission for permitting the charging of the battery 104. Then, the MPU 101 proceeds to step S304.

In step S303, the MPU 101 sets a battery charging inhibition for inhibiting the charging of the battery 104. Then, the MPU 101 proceeds to step S304.

In step S304, the MPU 101 determines whether the device 103 compliant with the USB PD standard is connected to the USB terminal of the power supply control unit 102. In a case where the MPU 101 determines that the device 103 compliant with the USB PD standard is connected (YES in step S304), the MPU 101 proceeds to step S305. In a case where the MPU 101 determines that the device 103 compliant with the USB PD standard is not connected (NO in step S304), the MPU 101 proceeds to step S306.

In step S305, the MPU 101 performs a battery charging process to charge the battery 104.

In step S306, the MPU 101 determines whether the recording start switch of the switch operation unit 107 has been pressed. In a case where the MPU 101 determines that the recording start switch has been pressed (YES in step S306), the MPU 101 proceeds to step S307. In a case where the MPU 101 determines that the recording start switch has not been pressed (NO in step S306), the MPU 101 proceeds to step S308.

In step S307, the MPU 101 performs moving image capturing. In moving image capturing, audio is input from the external microphone 115 when the external microphone 115 is connected to the external microphone input 110, and audio is input from the built-in microphone 109 when the external microphone 115 is not connected. When the moving image capturing is ended, the MPU 101 proceeds to step S308.

In step S308, the MPU 101 checks the operation mode and determines whether the operation mode is the moving image capture mode. In a case where the MPU 101 determines that the operation mode is the moving image capture mode (YES in step S308), the MPU 101 returns to step S301. In step S301, the MPU 101 repeats the operation related to moving image capturing described above. If the MPU 101 determines that the operation mode is not the moving image capture mode (NO in step S308), the MPU 101 terminates the moving image capture process. Then, the MPU 101 returns to the flowchart illustrated in FIG. 2.

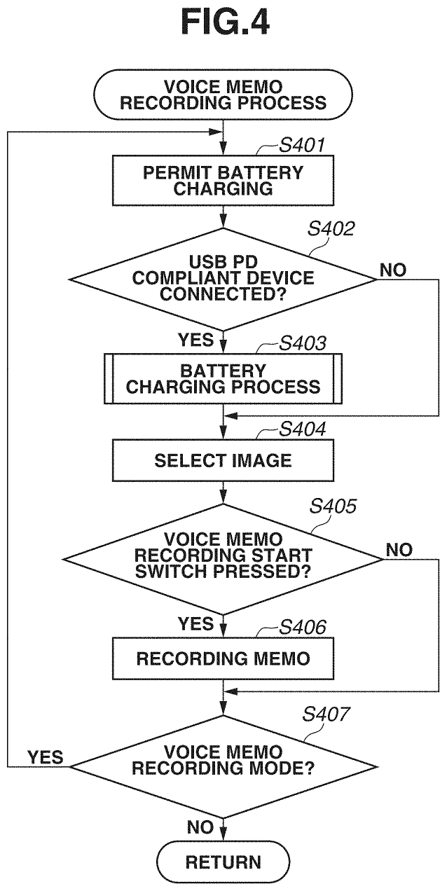

In step S207 of FIG. 2, the MPU 101 performs the voice memo recording process. When the voice memo recording process is ended, the MPU 101 returns to step S201. In step S201, the MPU 101 repeats the operation described above. Here, an example of the voice memo recording process performed in step S207 of FIG. 2 will be described with reference to the flowchart of FIG. 4. FIG. 4 is a flowchart illustrating the example of the voice memo recording process in the first and second exemplary embodiments.

In step S401, the MPU 101 sets a battery charging permission for permitting the charging of the battery 104.

In step S402, the MPU 101 determines whether the device 103 compliant with the USB PD standard is connected to the USB terminal of the power supply control unit 102. In a case where the MPU 101 determines that the device 103 compliant with the USB PD standard is connected (YES in step S402), the MPU 101 proceeds to step S403. In a case where the MPU 101 determines that the device 103 compliant with the USB PD standard is not connected (NO in step S402), the MPU 101 proceeds to step S404.

In step S403, the MPU 101 performs a battery charging process to charge the battery 104.

In step S404, the MPU 101 selects a still image in which a voice memo is to be recorded based on a user operation on the switch operation unit 107.

In step S405, the MPU 101 determines whether a voice memo recording start switch of the switch operation unit 107 has been pressed. In a case where the MPU 101 determines that the voice memo recording start switch has been pressed (YES in step S405), the MPU 101 proceeds to step S406. In a case where the MPU 101 determines that the voice memo recording start switch has not been pressed (NO in step S405), the MPU 101 proceeds to step S407.

In step S406, the MPU 101 records a voice memo using the voice memo microphone 108. The voice memo is recorded in association with the still image selected in step S404. When the recording of the voice memo is ended, the MPU 101 proceeds to step S407.

In step S407, the MPU 101 checks the operation mode and determines whether the operation mode is the voice memo recording mode. In a case where the MPU 101 determines that the operation mode is the voice memo recording mode (YES in step S407), the MPU 101 returns to step S401 and the MPU 101 repeats the operation related to the voice memo recording described above. In a case where the MPU 101 determines that the operation mode is not the voice memo recording mode (NO in step S407), the MPU 101 terminates the voice memo recording process, and the MPU 101 returns to the flowchart illustrated in FIG. 2.

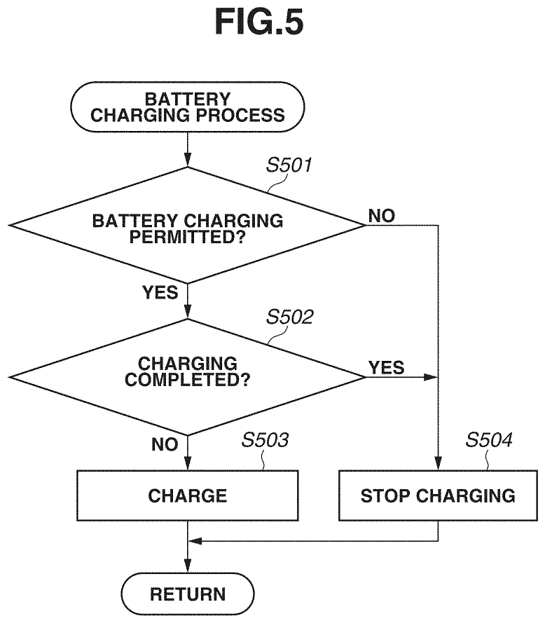

An example of the battery charging process performed in step S305 of FIG. 3 and in step S403 of FIG. 4 will be described with reference to the flowchart of FIG. 5. FIG. 5 is a flowchart illustrating an example of the battery charging process in the first and second exemplary embodiments.

In step S501, the MPU 101 determines whether the battery charging is permitted. In a case where the MPU 101 determines that the battery charging is permitted (YES in step S501), the MPU 101 proceeds to step S502. In a case where the MPU 101 determines that the battery charging is inhibited (NO in step S501), the MPU 101 proceeds to step S504.

In step S502, the MPU 101 checks the charging state of the battery 104 and determines whether the charging of the battery 104 has been completed. In a case where the MPU 101 determines that the charging of the battery 104 has not completed (NO in step S502), the MPU 101 proceeds to step S503. In a case where the MPU 101 determines that the charging of the battery 104 has been completed (YES in step S502), the MPU 101 proceeds to step S504.

In step 503, the MPU 101 controls the power supply control unit 102 to start or continue the charging of the battery 104. Then, the MPU 101 returns to the caller flowchart of FIG. 3 or FIG. 4.

In step 504, the MPU 101 controls the power supply control unit 102 to stop the charging of the battery 104. The MPU 101 then proceeds to the caller flowchart of FIG. 3 or FIG. 4.

As described above, in the first exemplary embodiment, in a case where the external microphone 115 is to be used at the time of moving image capturing, the battery 104 is not allowed to be charged because a high-performance microphone is assumed to be used as the external microphone 115. This avoids the audio to be recorded from being influenced by noise that can be caused by the charging operation of the battery. On the other hand, at the time of moving image capturing with the use of the built-in microphone 109, the battery 104 is allowed to be charged. In such a manner, according to the first exemplary embodiment, it is possible to achieve appropriate charging control of the battery 104 in accordance with the intended use of a microphone in performing operations involving audio recording. The first exemplary embodiment described above is merely an example, and the relationship between the microphone used and the charging control is not limited to this example.

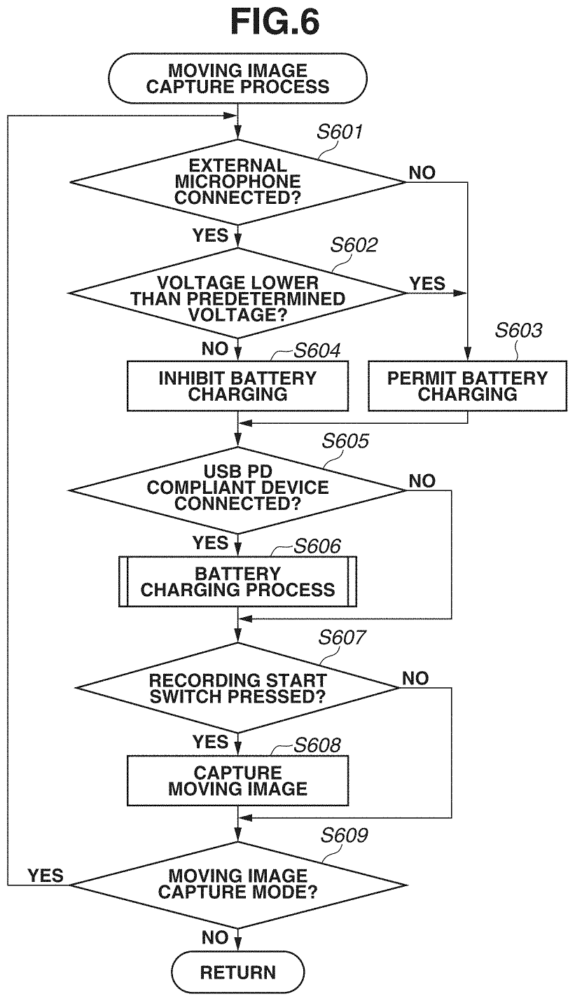

A description will be given of operation related to charging control with the use of a microphone by an electronic device 100 according to a second exemplary embodiment. The second exemplary embodiment is similar to the first exemplary embodiment described above except for a moving image capture process. Thus, only the moving image capture process in the second exemplary embodiment will be described below. FIG. 6 is a flowchart illustrating an example of the moving image capture process in the second exemplary embodiment. Each process in the flowchart illustrated in FIG. 6 is controlled by an MPU 101 of the electronic device 100 executing a program stored in a memory.

In step S601, the MPU 101 determines whether an external microphone 115 is connected to an external microphone input 110. In a case where the MPU 101 determines that the external microphone 115 is not connected (NO in step S601), the MPU 101 proceeds to step S603. In a case where the MPU 101 determines that the external microphone 115 is connected (YES in step S601), the MPU 101 proceeds to step S602.

In step S602, the MPU 101 checks the voltage of a battery 104 and determines whether the voltage of the battery 104 is lower than a predetermined voltage. In a case where the MPU 101 determines that the voltage of the battery 104 is lower than the predetermined voltage (YES in step S602), the MPU 101 sets a charging priority mode in which the charging of the battery 104 is prioritized. Then, the MPU 101 proceeds to step S603. If the MPU 101 determines that the voltage of the battery 104 is not lower than the predetermined voltage (NO in step S602), the MPU 101 sets an audio quality priority mode in which the quality of the audio to be recorded is prioritized. Then, the MPU 101 proceeds to step S604.

In step S603, the MPU 101 sets a battery charging permission for permitting the charging of the battery 104. Then, the MPU 101 proceeds to step S605.

In step S604, the MPU 101 sets a battery charging inhibition for inhibiting the charging of the battery 104. Then, the MPU 101 proceeds to step S605.

In step S605, the MPU 101 determines whether a device 103 compliant with the USB PD standard is connected to a USB terminal of a power supply control unit 102. In a case where the MPU 101 determines that the device 103 compliant with the USB PD standard is connected (YES in step S605), the MPU 101 proceeds to step S606. In a case where the MPU 101 determines that the device 103 compliant with the USB PD standard is not connected (NO in step S605), the MPU 101 proceeds to step S607.

In step S606, the MPU 101 performs a battery charging process to charge the battery 104.

In step S607, the MPU 101 determines whether a recording start switch of a switch operation unit 107 has been pressed. In a case where the MPU 101 determines that the recording start switch has been pressed (YES in step S607), the MPU 101 proceeds to step S608. In a case where the MPU 101 determines that the recording start switch has not been pressed (NO in step S607), the MPU 101 proceeds to step S609.

In step S608, the MPU 101 performs moving image capturing. In the moving image capturing, audio is input from the external microphone 115 when the external microphone 115 is connected to the external microphone input 110, and audio is input from a built-in microphone 109 when the external microphone 115 is not connected. When the moving image capturing has been completed, the MPU 101 proceeds to step S609.

In step S609, the MPU 101 checks the operation mode and determines whether the operation mode is the moving image capture mode. In a case where the MPU 101 determines that the operation mode is the moving image capture mode (YES in step S609), the MPU 101 returns to step S601. In a case where the MPU 101 determines that the operation mode is not the moving image capture mode (NO in step S609), the MPU 101 terminates the moving image capture process. Then, the MPU 101 returns to the flowchart illustrated in FIG. 2.

In the second exemplary embodiment, the voltage of the battery 104 is checked and, based on the voltage of the battery 104, the operation of the electronic device 100 is switched between the operation in which battery charging is prioritized and the operation in which the quality of audio to be recorded is prioritized. In a case where the voltage of the battery 104 is lower than the predetermined voltage, the charging of the battery 104 is prioritized. According to the second exemplary embodiment, it is possible to achieve appropriate charging control of the battery 104 in accordance with the intended use of a microphone and the voltage of the battery 104 when operation involving audio recording is performed.

The above-described various functions, processes, or methods of the first and second exemplary embodiments can also be implemented by a personal computer, microcomputer, central processing unit (CPU), or microprocessor executing a program. Hereinafter, in a third exemplary embodiment, such a personal computer, microcomputer, CPU, or microprocessor will be called a “computer X”. In addition, in the third exemplary embodiment, the program for controlling the computer X and implementing the above-described various functions, processes, or methods in the first and second exemplary embodiments will be called a “program Y”.

The above-described various functions, processes, or methods in the first and second exemplary embodiments are implemented by the computer X executing the program Y. In this case, the program Y is supplied via a computer-readable storage medium to the computer X. The computer-readable storage medium in the third exemplary embodiment includes at least one of a hard disk device, magnetic storage device, optical storage device, magneto-optical storage device, memory card, volatile memory, and non-volatile memory. The computer-readable storage medium in the third exemplary embodiment is a non-transitory storage medium.

While aspects of the disclosure are described with reference to exemplary embodiments, it is to be understood that the aspects of the disclosure are not limited to the exemplary embodiments. The scope of the following claims is to be accorded the broadest interpretation so as to encompass all such modifications and equivalent structures.

This application claims the benefit of Japanese Patent Application No. 2020-100041, filed Jun. 9, 2020, which is hereby incorporated by reference herein in its entirety.

What is claimed is:

1. An electronic device comprising:
a charging unit that charges a battery; and
a control unit that inhibits the charging unit from charging the battery in a case where audio recording using a first microphone is performed, and permits the charging unit to charge the battery in a case where audio recording using a second microphone different from the first microphone is performed.

2. The electronic device according to claim 1, further comprising a determination unit that determines whether to perform audio recording using the first microphone.

3. The electronic device according to claim 1, wherein, in performing audio recording using the first microphone, the control unit permits the charging unit to charge the battery in a case where a voltage of the battery is lower than a predetermined voltage.

4. The electronic device according to claim 1, wherein the first microphone is a microphone connectable to the electronic device, and the second microphone is a microphone included in the electronic device.

5. The electronic device according to claim 1, wherein the charging unit is inhibited from charging the battery in a case where the first microphone is connected to the electronic device and the electronic device performs moving image capturing.

6. A method comprising:
causing a charging unit to charge a battery;
inhibiting the charging unit from charging the battery in a case where audio recording using a first microphone is performed; and
permitting the charging unit to charge the battery in a case where audio recording using a second microphone different from the first microphone is performed.

7. The method according to claim 6, further comprising determining whether to perform audio recording using the first microphone.

8. The method according to claim 6, wherein, in performing audio recording using the first microphone, the charging unit is permitted to charge the battery in a case where a voltage of the battery is lower than a predetermined voltage.

9. The method according to claim 6, wherein the first microphone is a microphone connectable to the electronic device, and the second microphone is a microphone included in the electronic device.

10. The method according to claim 6, wherein the charging unit is inhibited from charging the battery in a case where the first microphone is connected to the electronic device and the electronic device performs moving image capturing.

11. A non-transitory storage medium that stores a program causing a computer to execute a method, the method comprising:
causing a charging unit to charge a battery;
inhibiting the charging unit from charging the battery in a case where audio recording using a first microphone is performed; and
permitting the charging unit to charge the battery in a case where audio recording using a second microphone different from the first microphone is performed.
